(19) United States
(12) Patent Application Publication
(10) Pub. No.: US 2008/0237684 A1
(43) Pub. Date: Oct. 2, 2008

(54) Method of manufacturing a nanowire transistor, a nanowire transistor structure, a nanowire transistor field

(76) Inventors: Michael Specht, Muenchen (DE); Franz Hofmann, Muenchen (DE); Andreas Kux, Haar (DE)

Correspondence Address: SLATER & MATSIL, L.L.P., 17950 PRESTON ROAD, SUITE 1000, DALLAS, TX, 75252, US

(21) Appl. No.: 11/728,587

(22) Filed: Mar. 26, 2007

(51) Int. Cl. H01L 29/788; H01L 21/336

(52) U.S. Cl. 257/316; 438/257; 257/E29.3; 257/E21.409; 977/762

(57) ABSTRACT

A method of manufacturing a nanowire transistor includes oxidizing at least a portion of a semiconductor carrier. The semiconductor carrier includes a first carrier portion and a second carrier portion above the first carrier portion. A portion of the oxidized portion is removed, thereby forming an oxide spacer between a portion of the second carrier portion and the first carrier portion. A gate region is formed above at least a portion of the second carrier portion, and a first source/drain region and a second source/drain region are formed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a side view of a nanowire non-volatile memory cell in accordance with an embodiment of the present invention;

FIG. 1B illustrates a cross sectional view of a nanowire non-volatile memory cell taken along the section line A-A′ as shown in FIG. 1A in accordance with an embodiment of the present invention;

FIG. 2 illustrates a method of manufacturing a nanowire transistor in accordance with an embodiment of the present invention;

FIGS. 3A to 3H illustrate cross-sectional views of the memory cell in various states of manufacturing in accordance with an embodiment of the present invention;

FIG. 4 illustrates a portion of a nanowire non-volatile NAND memory field in accordance with an embodiment of the present invention;

FIG. 5A illustrates a method of manufacturing a nanowire transistor in accordance with an embodiment of the present invention; and

FIG. 5B illustrates a method of manufacturing a nanowire structure in accordance with an embodiment of the present invention.

### DETAILED DESCRIPTION OF ILLUSTRATIVE EMBODIMENTS

As used herein the terms connected and coupled are intended to include both direct and indirect connection and coupling, respectively.

The invention relates to a method of manufacturing a nanowire transistor, a nanowire transistor structure, a nanowire transistor field and a computer program product.

Non-volatile memory devices are widely used, and their further adoption and implementation will require improved scalability, lower programming voltages, faster programming and access speeds, and longer device life. In particular, the planar structure of conventional non-volatile memory devices limits memory cell scalability, particularly below a cell pitch of 50 nm. In addition, the thickness of the tunnel oxide layer in a conventional non-volatile memory device presents a tradeoff between the required programming voltage and retention time. A thin tunnel oxide layer (of e.g., 2.5 nm) can provide a lower programming voltage, albeit with the tradeoff of shorter retention time. A thicker tunnel oxide layer provides a better retention time, but results in the disadvantage of a higher required programming voltage.

It should be pointed out that, although the following exemplary embodiments describe nanowire non-volatile memory cells in more detail, the invention is not limited to a non-volatile memory cell, not even to a memory cell. The invention could also be used for a nanowire transistor such as a nanowire field effect transistor. In this general case, instead of a charge storage region, which is provided in a nanowire non-volatile memory cell, a gate insulation region is provided, e.g., made of an oxide layer.

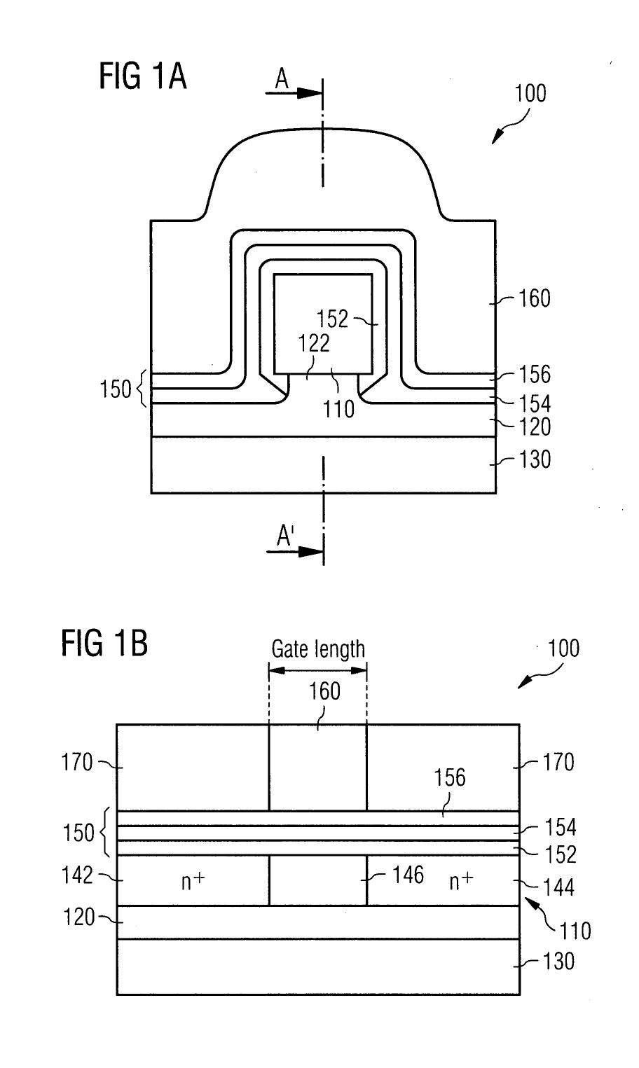

FIG. 1A and FIG. 1B illustrate a side view (FIG. 1A) and a cross sectional view along cross sectional line A-A′ of FIG. 1A (FIG. 1B), respectively, of a nanowire non-volatile memory cell in accordance with an embodiment of the invention.

Referring to the side view illustrated in FIG. 1A, a nanowire non-volatile memory cell 100 includes an elongated nanowire structure 110, which is formed proximate to the surface of an insulation layer 120 (e.g., a layer made of silicon oxide SiO₂). The elongated nanowire structure 110 has a three dimensional extension in a length direction, a width direction and in a height direction. The insulation layer 120, in the following also referred to as second carrier portion 120, is formed on the upper surface of a bulk semiconductor carrier 130 (e.g., bulk silicon substrate), in the following also referred to as first carrier portion 130. The nanowire structure 110 is formed from a bulk semiconductor material, e.g., bulk silicon. In an alternative embodiment of the invention, the bulk semiconductor material may be made of a compound semiconductor material such as a IV-IV-bulk semiconductor material (such as silicon germanium (SiGe)), a III-V-bulk semiconductor material (such as gallium arsenide (GaAs)) or a II-VI-bulk semiconductor material. Other appropriate bulk semiconductor materials may also be used in alternative embodiments of the invention.

As shown, the nanowire non-volatile memory cell 100 further includes a drain region 142, a source region 144 and an active region 146 between the drain region 142 and the source region 144.

A memory structure 150 is disposed above the drain region 142, the source region 144 and the active region 146, e.g., a charge storage region, shown in an exemplary embodiment of the invention as charge trapping region, which extends longitudinally (horizontally as shown in FIG. 1B) over at least a portion of the active region 146. As shown, the charge trapping region includes a tunnel oxide layer 152 on or above the active region 146, a charge trapping layer 154 on or above the tunnel oxide layer 152, and a top oxide layer 156 on or above the charge trapping layer 154. In exemplary embodiments of the invention, the tunnel oxide layer 152 and the top oxide layer 156 are composed of an oxide or similar material (the tunnel oxide layer 152 may be formed from silicon oxide, the top oxide layer 156 may be formed from a high-k dielectric material such as aluminum oxide). The charge trapping layer 154 may be made of a material being selected of a group of materials that consists of silicon nitride, yttrium oxide, hafnium oxide, zirconium oxide, an aluminate, an alloy of the above mentioned materials, etc.

In an embodiment of the invention, the charge trapping region includes a tunnel dielectric, a trapping dielectric, and a blocking dielectric between the gate region and the bulk semiconductor carrier. The tunnel dielectric may include a plurality of layers, e.g., a first oxide layer, a nitride layer disposed above the first oxide layer, and a second oxide layer disposed above the nitride layer. The first oxide layer may have a thickness in the range of approximately 1 nm to approximately 2 nm (e.g., approximately 1.5 nm), the nitride layer may have a thickness in the range of approximately 1 nm to approximately 3 nm (e.g., approximately 2 nm), and the second oxide layer having a thickness in the range of approximately 1 nm to approximately 2 nm (e.g., approximately 1.5 nm). The blocking dielectric may include silicon oxide or a dielectric material having a dielectric constant that is greater than the dielectric constant of silicon oxide. Furthermore, the blocking dielectric may include a dielectric material having a dielectric constant that is greater than the dielectric constant of silicon oxide and an energy band gap above 5 eV. In an embodiment of the invention, the blocking dielectric may include aluminum oxide or hafnium silicate.

In another embodiment of the invention, the charge trapping region includes one or more dielectric layers (e.g., two dielectric layers, three dielectric layers or even four or more dielectric layers) in a charge trapping layer stack trapping electrical charge carriers.

As those skilled in the art will appreciate, the memory structure 150 may be a single-level structure or single-bit structure, or alternatively, a multi-level structure or a multi-bit structure. In a particular embodiment of the invention, the memory structure 150 is a multi-level charge trapping structure.

In another embodiment of the invention, the charge storage region is a floating gate region, which may be configured as a single-level structure or as a single-bit structure, or alternatively, as a multi-level structure or as a multi-bit structure.

Furthermore, a gate region 160, e.g., made of poly-silicon, is disposed above the memory structure 150.

As shown in FIG. 1B, isolating material 170 such as an oxide, e.g., silicon oxide is provided next to the gate region 160 for isolating respectively adjacent gate regions 160 of adjacent non-volatile memory cells 100.

The gate region 160, the memory structure 150, the drain region 142, the source region 144 and the active region 146 are elements of a transistor which serves as the non-volatile memory cell 100, and the isolation regions made of the isolating material 170 serve as isolations between adjacently-located nanowire non-volatile memory cells coupled to separate word lines.

Referring to the construction of the elongated nanowire structure 110, the active region of which may be a p-doped area, in which an electrically conductive channel may be formed in response to the application of appropriate gate, source and drain voltages, respectively, thereby enabling a current flow through the channel from the drain region 142 to the source region 144. Furthermore, the elongated nanowire structure 110 includes the drain region 142 and the source region 144, which may be n-doped or n⁺-doped. Alternative doping profiles may be implemented for the non-volatile memory cell 100. By way of example, the active region 146 may include an n-doped area, and the drain region 142 and the source region 144 may have a p-doped profile or a p⁺-doped profile.

An exemplary manufacturing process of the elongated nanowire structure 110 will be described in more detail below.

In a particular embodiment of the invention, the tunnel oxide layer 152 is 4.0 nm thick (as measured vertically in FIG. 1A) or thicker, for example, 4.25 nm, 4.5 nm, 4.75 nm, 5.0 nm, 5.25 nm or thicker. The tunnel oxide layer 152 of such a thickness, and particularly a tunnel oxide layer 152 thicker than 3.5 nm has not been previously recommended since the erase process is hindered by the very low tunneling probability of holes from the substrate into the trapping layer. The implementation of a thicker tunnel oxide layer 152 has long been sought, as a thicker layer provides longer cell life over a greater number of program and erase cycles. Alternatively, the memory cell 100 in accordance with an embodiment of the invention may employ a tunnel oxide layer 152 of a conventional thickness (e.g., 2.5 nm to 3.5 nm). Such a configuration would allow faster cell programming at lower voltages and lower fields due to the reduction of the effective thickness of the tunnel oxide layer 152, the elongated nanowire structure 110 provides.

In an alternative embodiment of the invention, the charge storage region includes a floating gate structure, in which an isolated (e.g., encapsulated) conductive layer is provided for storing the electric charge. Poly-silicon may be used for the conductive layer. In such an embodiment of the invention, a tunnel oxide layer is also provided which is configured as described above in the context of a charge trapping region. In another embodiment of the invention, the tunnel oxide layer has a thickness of greater than 4.0 nm and may be for example, 4.25 nm, 4.5 nm, 4.75 nm, 5.0 nm, 5.25 nm or thicker up to 10 nm. Furthermore, a control oxide layer may be provided on or above the conductive layer.

The gate region 160 provides electrical contact to the external environment (e.g., via a gate contact region (not shown), e.g., made of a silicide such as tungsten silicide) and may be composed of poly-silicon in accordance with one embodiment of the invention, although other materials such as a metal (e.g., tantalum nitride (TaN), titanium nitride (TiN), aluminium (Al), copper (Cu)), e.g., a metal having a suitably high work function may be used alternatively. When poly-silicon is used as the material for the gate region 160, the poly-silicon may be undoped poly-silicon, p-doped poly-silicon or n-doped poly-silicon.

The spacer portion 122 of the insulation layer 120 may be formed from an oxide, e.g., silicon oxide, in an alternative embodiment of the invention, from another isolating material. The spacer portion 122 is an artifact of the nanowire structure manufacturing process, which will be described in more detail below, and permits the construction of the non-volatile memory cell 100 in a silicon-on-insulator structure without the need for a conventional SOI wafer.

As will be described in more detail below, the manufacturing process in accordance with an embodiment of the invention provides techniques whereby memory cells can be manufactured in an SOI structure without the need for an SOI base wafer, thereby achieving higher performance characteristics of SOI-based memory cells at significantly lower cost. In a particular embodiment of the invention, the spacer portion 122 has a width in the range of about 5 nm to about 30 nm and a height of about 10 nm to about 40 nm, although other dimensions may be used in alternative embodiments of the invention.

The memory cell 100 also includes the drain region 142. In a particular embodiment of the invention, the drain region 142 of the elongated nanowire structure 110 is an n⁺-doped portion of the elongated nanowire structure 110, although in an alternative embodiment of the invention, the drain region 142 of the elongated nanowire structure 110 may have a p-doped profile.

The non-volatile memory cell 100 further includes the source region 144. In a particular embodiment of the invention, the source region 144 of the elongated nanowire structure 110 is an n⁺-doped portion of the elongated nanowire structure 110, although in an alternative embodiment of the invention, the source region 144 of the elongated nanowire structure 110 may have a p-doped profile.

Also included in the non-volatile memory cell 100 are isolation regions 170 operable as isolating barriers between adjacently-located memory cells. In a particular embodiment of the invention, the isolation regions 170 are composed of silicon oxide. In one embodiment of the invention, the isolation regions 170 may be formed of TEOS (Tetra-Ethyl-Ortho-Silicate) or SOG (Spin-on-Glass) material operable to provide the desired isolation between adjacent memory cells.

In accordance with an embodiment of the invention, the gate region 160 has a cross-section (in the width direction of the elongated nanowire structure 110) which is rounded in a semi-cylindrical shape, e.g., around at least 180 degrees of the cross-section, the exemplary embodiment shown in FIG. 1A showing a cross-section of the rounded structure being rounded by about 330 degrees. In further embodiments of the invention, the cross-section over which the rounding may be provided ranges from about 190 degrees to 350 degrees, e.g., from about 210 degrees to 330 degrees, e.g., from about 240 degrees to 290 degrees. The rounded cross-section effectively lengthens the gate junction compared to the gate length of a conventional planar non-volatile memory cell. The greater effective gate length of the nanowire transistor in accordance with an embodiment of the invention means, e.g., that a memory cell employing a charge storage region of conventional thicknesses will achieve faster programming speeds at lower programming voltages. Alternatively, the nanowire transistor can be implemented with a thicker tunnel dielectric layer to improve retention, while maintaining programming timing and voltage levels achieved in conventional devices. Furthermore, the injection behavior of the non-volatile memory cell 100 becomes more homogeneous.

Furthermore, due to imperfections in the photolithographic/semiconductor processing steps, the cross-section over which rounding occurs may not be perfectly cylindrical. In such instances, the rounded cross-section will have maximum and minimum radii. In accordance with an embodiment of the invention, the maximum radius is defined as being no larger than 1.5 times the minimum radius within the rounded cross-section. Further embodiments of the ratio between maximum and minimum radii include 1.4, 1.3, 1.2, 1.1. FIG. 1A illustrates an exemplary embodiment of the invention in which the maximum radius within the rounded cross-section is 1.3 when normalized to the minimum radius.

As further shown in FIG. 1A, the memory structure 150, made of the tunnel oxide layer 152, the charge trapping layer 154 (e.g., a silicon nitride layer), and the top oxide layer 156, is co-extensively formed around the rounded cross-section, although in alternative embodiments of the invention, the memory structure 150 does not extend around the entire rounded cross-section. The construction of the gate region 160 provides for low gate-to-adjacent gate coupling, as the memory structure envelopes a large part (if not all) of the elongated nanowire structure 110, thereby improving the so-called short channel effect occurring in a conventional planar memory cell arrangement and even in a conventional fin-shaped memory cell arrangement.

In an embodiment of the invention, the cross-sectional radius (in average) of the gate region 160 is about 8 nm, and the thickness dimensions (in average) of the tunnel oxide layer 152, the charge trapping layer 154, and the top oxide layer 156, are about 4.0 nm, about 7 nm and about 5 nm, respectively. These dimensions are exemplary and others may be used in alternative embodiments of the invention. For example, the thickness of the tunnel oxide layer 152 may range from about 4.0 nm to about 6.5 nm, which is significantly greater than the thickness of a conventional tunnel oxide layer, such a thickness aiding in the retention of the tunnel oxide layer over a high number of programming and erase cycles. Exemplary thicknesses of the tunnel oxide layer 152 include 4.0 nm, 4.25 nm, 4.5 nm, 4.75 nm, 5.0 nm, 5.25 nm, 5.5 nm, 5.75 nm, and 6.0 nm. Further exemplary, the thickness of the charge trapping layer 154 may range from about 4 nm to about 10 nm, and the thickness of the top oxide layer 156 may range from about 3 nm to about 8 nm. In particular, if for the top dielectric a material with higher dielectric constant then SiO₂ is used, for instance Al₂O₃ or Hf based, then a substantially larger thickness of approximately 10 nm to approximately 20 nm for the top dielectric may be required. Alternatively the top dielectric may be a combination of SiO₂ and a material with higher dielectric constant than SiO₂. The indicated dimensions are exemplary, and those skilled in the art will appreciate that layers of other dimensions may be used in alternative embodiments of the invention.

In an alternative embodiment, the nanowire active region 146 has a rounded cross section of about 190 degrees. Further particularly, the largest radius within the 190 degree rounded cross section is a ratio of 1.5 when normalized to the shortest radius of the rounded cross section.

In another embodiment of the invention, the drain region 142, the active region 146 and the source region 144 are rounded around at least 180 degrees, forming rounded cross-sectional areas, respectively. In further specific embodiments of the invention, each of the rounded cross-sectional areas ranges from about 190 degrees to about 350 degrees, from about 210 degrees to about 330 degrees, or from about 240 degrees to about 290 degrees. Further specifically, the ratio of maximum radius to minimum radius within the rounded cross-sectional areas ranges from about 1.5 to about 1.0. The drain region 142 and the source region 144 are implanted with the desired doping profiles and annealed at the desired temperature to form respective drain and source junctions. In a particular embodiment of the invention, the gate region 160, the drain region 142, the active region 146 and the source region 144 are formed concurrently, and accordingly have substantially the same rounded cross-sectional areas and ratio of maximum radius to minimum radius.

In an alternative embodiment of the invention, the drain region 142 and the source region 144 are formed in a manner dissimilar to the active region 146. As an example, the drain region 142 and the source region 144 may have different rounded cross-sectional areas from that of the active region 146, or have a different ratio of maximum radius to minimum radius. In a further alternative embodiment of the invention, the drain region 142 and the source region 144 may be formed in a shape different from that of the active region 146.

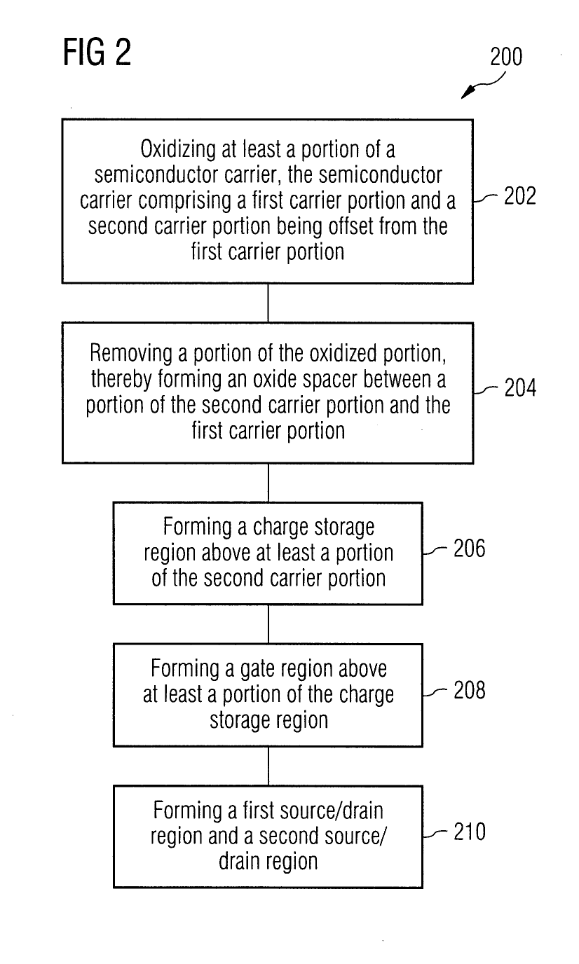

FIG. 2 illustrates a method of manufacturing a nanowire transistor in accordance with an embodiment of the invention in a flow diagram 200. In an alternative embodiment of the invention, a similar method of manufacturing an integrated circuit including a nanowire transistor is provided.

The method starts at 202, at which at least a portion of a semiconductor carrier, the semiconductor carrier comprising a first carrier portion and a second carrier portion being offset from the first carrier portion, is oxidized.

At 204, a portion of the oxidized portion is removed, thereby forming an oxide spacer between a portion of the second carrier portion and the first carrier portion.

At 206, a charge storage region is formed above at least a portion of the second carrier portion.

At 208, a gate region is formed above at least a portion of the charge storage region.

At 210, a first source/drain region and a second source/drain region are formed.

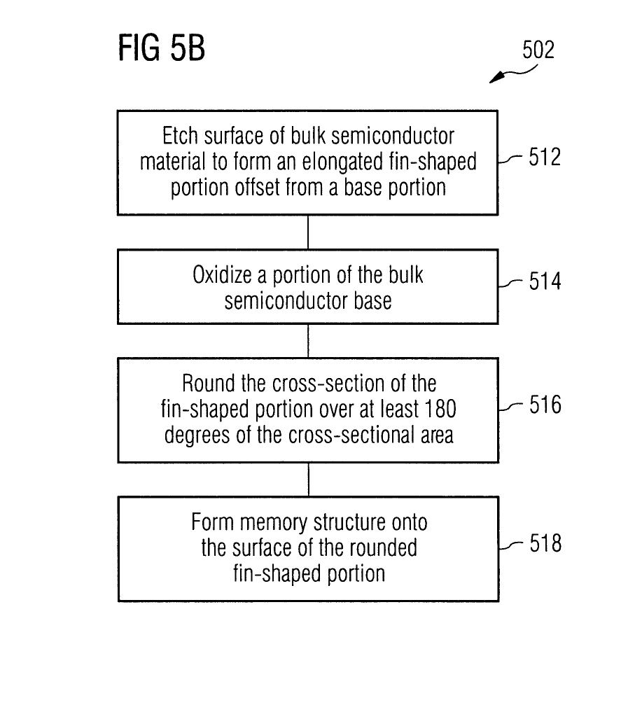

FIG. 5A illustrates a method of manufacturing a nanowire non-volatile memory cell in accordance with an embodiment of the invention in a flow diagram 500.

The method starts at 502, whereby an elongated nanowire structure 110 is formed from semiconductor material. In a specific embodiment of the invention, the elongated nanowire structure 110 is formed to have a rounded cross-sectional area of at least 180 degrees. FIGS. 1A and 1B illustrate exemplary embodiments of this elongated nanowire structure 110 and exemplary manufacturing processes are described below in more detail.

It should be noted that in an alternative embodiment of the invention, the elongated nanowire structure 110 does not necessarily be rounded.

At 504, gate material is deposited on a first portion of the elongated nanowire structure 110, thereby forming the gate region 160.

At 506 and 508, respective second and third portions of the elongated nanowire structure 110 are doped and optionally annealed to form the drain region 142 and the source region 144. It should be mentioned that the drain region 142 and the source region 144 may in one embodiment of the invention be formed simultaneously in one common process.

The gate region 160, the drain region 142 and the source region 144 of the elongated nanowire structure 110 are components of a transistor that is operable as a memory cell in accordance with an embodiment of the invention. As those skilled in the art will appreciate, manufacture of a nanowire memory cell transistor in accordance with FIG. 5A and FIG. 5B is not limited to the particular sequence illustrated, and either the drain or source annealing steps may precede the gate deposition process in accordance with an alternative embodiment of the invention.

FIG. 5B illustrates an exemplary embodiment of the invention of process 502 shown in FIG. 5A, whereby an elongated nanowire structure 110 is formed.

Initially at 512, a first surface of a bulk semiconductor material substrate is etched to form an elongated fin-shaped portion, in other words, an elongated raised portion (e.g., the second carrier portion), of the bulk semiconductor material, and a base of the bulk semiconductor material (e.g., the first carrier portion). In a particular embodiment of the invention, the bulk semiconductor material is silicon and the elongated fin-shaped portion has a substantially rectangular shape with a width and a height which are at least the desired radius of the elongated nanowire structure 110 to be formed. In a specific example, the fin-shaped portion extends 50 nm above the base of the bulk semiconductor material.

At 514, at least a portion of the base of the bulk semiconductor material is oxidized. Through this process, the base of the bulk semiconductor material is transformed into a semiconductor base layer 120, as shown in FIGS. 1A and 1B, and serves as a silicon-on-insulator (SOI) base substrate upon which the memory cell is constructed. The SOI base substrate provides improved performance compared to bulk semiconductor materials, and an embodiment of the present invention enables an implementation of this type of substrate and the accompanying performance enhancement while avoiding the costs for providing an SOI wafer as in a conventional approach.

At 516, the cross-section of the elongated fin-shaped portion is rounded over at least 180 degrees of its cross-sectional area along its width direction, thereby forming a rounded cross-sectional area. In a particular embodiment of the invention, the cross-sectional area over which the rounding is provided, includes at least the active region 146, the drain region 142, and the source region 144. In a further embodiment of the invention, the rounding process is performed over the entire length of the fin-shaped portion, the active region 146, the drain region 142, and the source region 144. Such an embodiment may be implemented in the construction of a NAND memory array, whereby the elongated nanowire structure 110 forms a NAND string of (serially) source-to-drain coupled memory cells. In such an embodiment, the rounding process is performed over the length of the nanowire structure 110 which forms the NAND string of memory cells.

It should be mentioned that the invention is not limited to a NAND architecture, but can also be applied to any other kind of memory field architecture such as a NOR architecture, for example.

As those skilled in the art will appreciate, variations in the semiconductor process may result in imperfections in the rounding process. In such embodiments of the invention, the rounded cross-sectional areas will have a minimum radius and a maximum radius. In accordance with an embodiment of the present invention, the maximum radius does not exceed about 1.5 times the minimum radius over the rounded cross-sectional areas. The rounding process may be performed by employing a conventional rounding thermal oxidation (RTO) process in which an oxide layer is grown over the rounded raised portion. In a specific embodiment of this process, the oxidation temperature is about 800° C. or higher, wherein higher oxidation temperatures help the formation of rounded surfaces. In another embodiment of the invention, hydrogen annealing is used to round the fin-shaped portion.

At 518, the memory structure is formed above or onto the surface of the elongated nanowire structure 110, the memory structure extending over at least a portion of the nanowire active region 146. As noted above, the memory structure may be, e.g., a charge trapping structure (in other words, a charge trapping region), such as an oxide-nitride-oxide layer structure, or a floating gate structure (in other words, a floating gate region). In exemplary embodiments of the invention, the memory structure extends from about 190 degrees to about 350 degrees around the active region 146. In other embodiments of the invention, the memory structure may extend from about 210 degrees to about 330 degrees or from about 240 degrees to about 290 degrees around the active region 146.

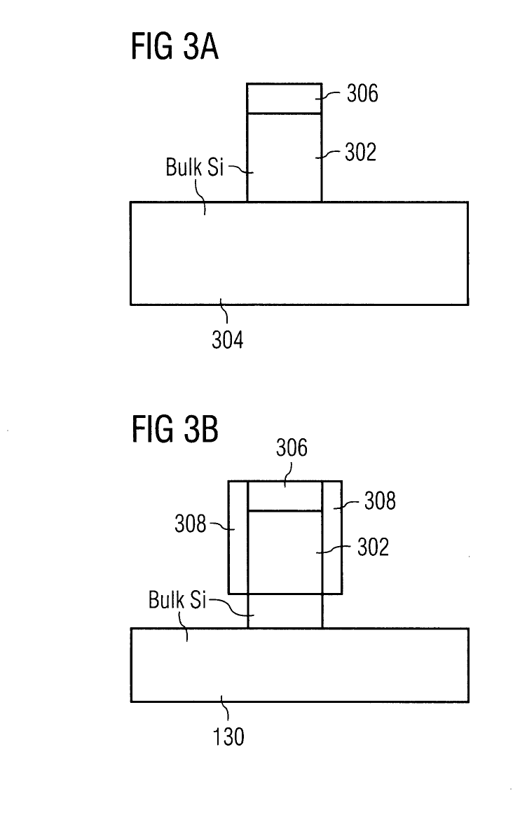

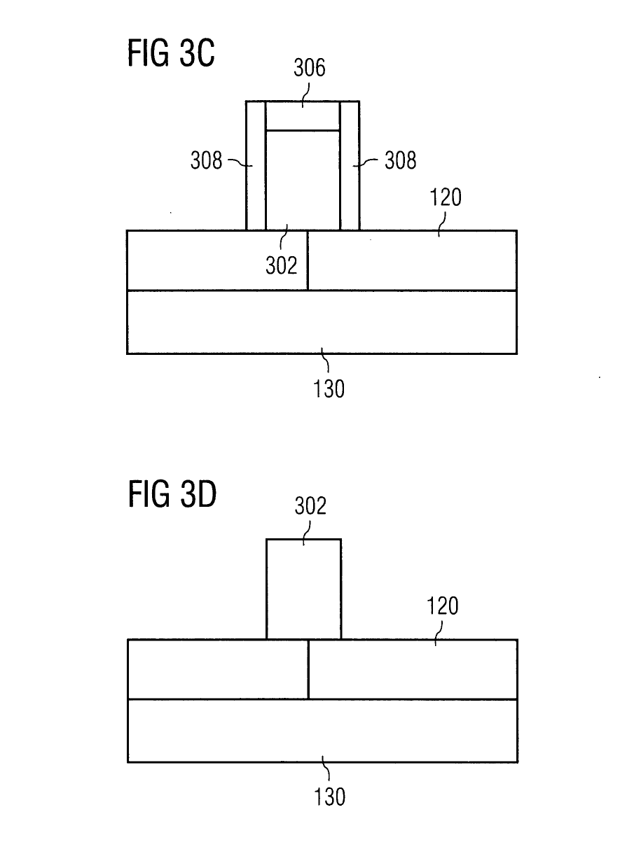

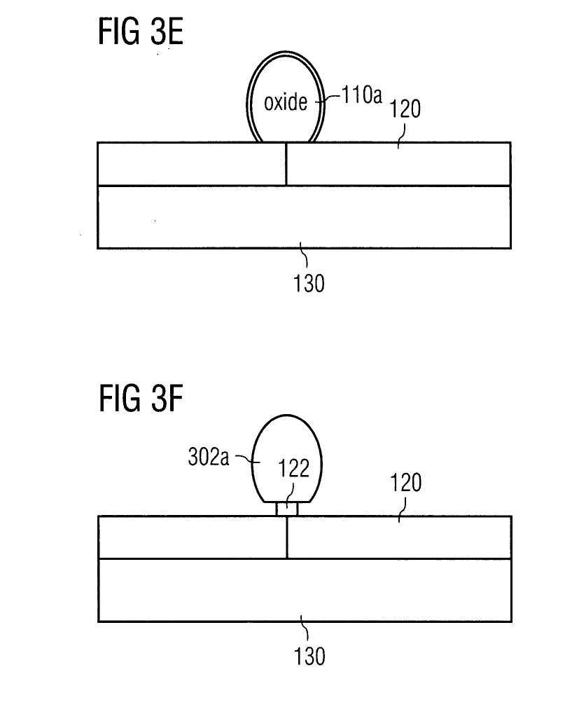

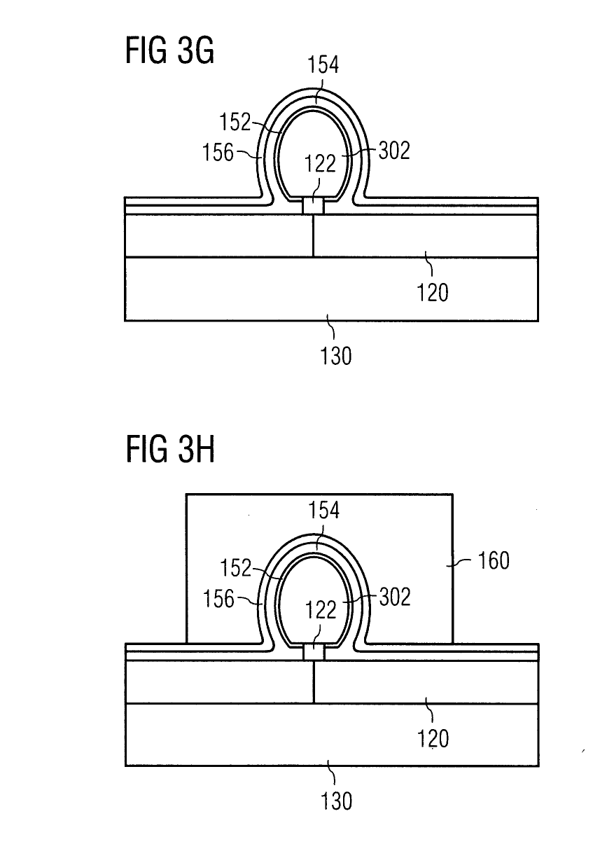

FIG. 3A to FIG. 3H illustrate cross-sectional views of the memory cell's active region 146 in various states of manufacture as described in FIG. 5A and FIG. 5B in accordance with an embodiment of the present invention.

FIG. 3A shows the construction of the active region after a silicon nitride hardmask 306 (in an alternative embodiment of the invention, a silicon nitride hardmask or a carbon hardmask or any other suitable hardmask may be used) has been applied to a substrate of bulk silicon and the bulk silicon has been etched to form a fin-shaped second carrier portion 302 and a base as the first carrier portion 304 of the bulk silicon material. In an exemplary embodiment of the invention, the fin-shaped portion 302 measures about 10 nm to about 40 nm in height (vertical dimension of FIG. 3A) and about 5 nm to about 30 nm in width (horizontal dimension of FIG. 3A). Of course, a fin-shaped portion 302 of other dimensions may be fabricated in alternative embodiments of the invention.

FIG. 3B shows the active region 146 after a nitride hardmask 308 has also been applied to the sidewalls of the fin-shaped portion 302, and the bulk silicon base 304 has been isotropically etched. In an exemplary embodiment of the invention, the bulk silicon base 304 is etched down about 50 nm to about 100 nm, thereby forming the bulk silicon substrate 130 therebelow.

FIG. 3C shows the active region 146 after oxidation of the bulk silicon material, thereby forming a silicon oxide layer as the insulation layer 120 (and the high performance silicon-on-insulator structure) upon which the active region 146 is formed.

FIG. 3D shows the active region 146 once the hardmask 306, 308 has been removed (e.g., by means of wet etching) from the fin-shaped portion.

FIG. 3E shows the active region 146 upon completion of a rounding thermal oxidation process. In a specific embodiment of this process, the oxidation temperature is 800° C. or higher, wherein higher temperatures help to form rounded surfaces. In another embodiment of the invention, hydrogen annealing is used to round the fin-shaped portion. Other techniques may be alternatively used to round the fin-shaped portion.

In accordance with one embodiment of the invention, the rounding process is performed concurrently along the active region 146, the drain region 142 and the source region 144, so that these regions are substantially uniform at this stage in the process. In another embodiment of the invention, the rounding operation is performed along the entire length of the elongated nanowire structure 110.

FIG. 3F shows the active region 146 after the oxide layer 110a surrounding the rounded fin-shaped portion 302 has been etched away, thus forming the nanowire active region 146. The insulation layer 120 is also etched down during the process, e.g., by about 50 nm to about 100 nm, thereby exposing a fin substrate portion. In the exemplary embodiment shown, the active region 146 is rounded over a predefined range (e.g., greater than 180 degrees, between about 190 degrees to about 350 degrees), and is not rounded over the surface area 302a, which is contacted by the fin substrate portion 122.

FIG. 3G shows the active region 146 after a memory structure, shown as an oxide-nitride-oxide (ONO) structure 152, 154, 156, has been formed over the nanowire active region 146. In an exemplary embodiment of the invention, the ONO structure 152, 154, 156 is formed around the active region 146 through top oxidation, e.g., using wet oxide in-situ stream generated oxide (ISSG) or high temperature oxide (HTO).

FIG. 3H illustrates the active region 146 after gate material 160 has been applied thereto. In a particular embodiment of the invention, the gate material is poly-silicon, although other contact materials may be used in alternative embodiments.

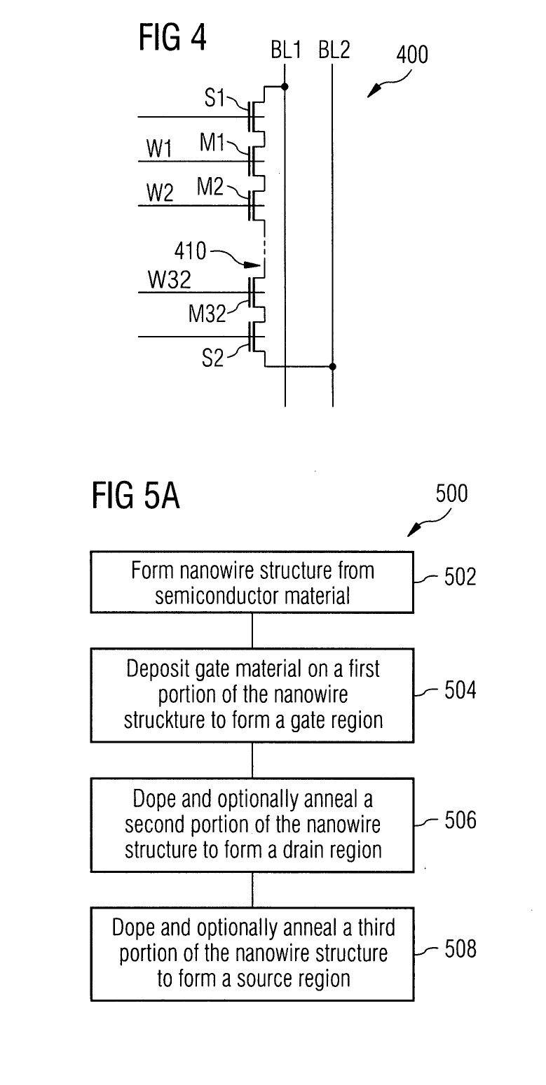

FIG. 4 illustrates a portion 400 of a NAND memory array implementing the nanowire transistor for use as a memory cell in accordance with an embodiment of the invention. The array portion 400 includes a first bit line BL1 and a second bit line BL2, which are coupled to select transistors S1 and S2, respectively. A NAND string 410 is composed of the nanowire structure 110 as described herein, each of the memory cells M1 to M32 formed as nanowire transistor non-volatile memory cell as described above. In an embodiment of the invention, the select transistors S1 and S2 may be formed in a similar way except that in this case, a gate insulation layer is formed instead of the memory structure in the memory cells. Each word line of a plurality of word lines W1 to W32 is coupled to the gate region of memory cells across a plurality of array portions. Thirty-two memory cells are shown in the nanowire NAND string 410, although a different number may be used in alternative embodiments of the invention.

As readily appreciated by those skilled in the art, the described processes may be implemented in hardware, software, firmware or a combination of these implementations as appropriate. As an example, each of the described processes may be carried out by semiconductor processing equipment known in the art. Furthermore, some or all of the described processes may be implemented as computer readable instruction code that is resident on a computer readable medium (removable disk, volatile or non-volatile memory, embedded processors, etc.), the instruction code operable to program a computer, semiconductor processing equipment, or other such programmable device to carry out the intended functions.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A method of manufacturing an integrated circuit having a nanowire transistor, the method comprising:
oxidizing at least a portion of a semiconductor carrier, the semiconductor carrier comprising a first carrier portion and a second carrier portion being disposed above the first carrier portion;
removing a portion of the oxidized portion, thereby forming an oxide spacer between a portion of the second carrier portion and the first carrier portion;
forming a charge storage region above at least a portion of the second carrier portion;
forming a gate region above at least a portion of the charge storage region; and
forming a first source/drain region and a second source/drain region adjacent the gate region.

2. The method of claim 1, further comprising:
rounding at least a part of a peripheral surface of the second carrier portion of the semiconductor carrier.

3. The method of claim 1, wherein forming the first source/drain region and the second source/drain region comprises doping a first portion and a second portion of the second carrier portion.

4. The method of claim 3, wherein forming the first source/drain region and the second source/drain region further comprises annealing the first portion and the second portion of the second carrier portion.

5. The method of claim 1, wherein the semiconductor carrier comprises silicon.

6. The method of claim 2, wherein rounding at least a part of the peripheral surface of the second carrier portion of the semiconductor carrier comprises applying a thermal oxidation to the second carrier portion.

7. The method of claim 2, wherein rounding at least a part of the peripheral surface of the second carrier portion of the semiconductor carrier comprises rounding the part of the peripheral surface such that at least 180° of a cross section is rounded to form a rounded cross section of the second carrier portion.

8. The method of claim 7, wherein rounding at least a part of the peripheral surface of the second carrier portion of the semiconductor carrier comprises rounding the part of the peripheral surface such that a range of 190° to 350° of a cross section is rounded to form a rounded cross section of the second carrier portion.

9. The method of claim 2, wherein rounding at least a part of the peripheral surface of the second carrier portion of the semiconductor carrier comprises hydrogen annealing the second carrier portion.

10. The method of claim 9, wherein hydrogen annealing the elongated raised portion comprises hydrogen annealing the second carrier portion at a temperature of about 800° C. or higher.

11. The method of claim 1, further comprising:
forming a gate-isolation region above at least a portion of the second carrier portion;
wherein the gate region is formed above at least a portion of the gate-isolation region.

12. The method of claim 1, wherein forming the charge storage region comprises forming a floating gate region.

13. The method of claim 1, wherein forming the charge storage region comprises forming a charge trapping region.

14. The method of claim 1, wherein forming the gate region comprises forming a poly-silicon gate region.

15. An integrated circuit comprising a nanowire transistor structure, the nanowire transistor structure comprising:
a bulk semiconductor carrier;
a nanowire structure formed on the bulk semiconductor carrier, the nanowire structure comprising:
a first source/drain region;
a second source/drain region;
an active region between the first source/drain region and the second source/drain region;
a charge storage region disposed above the active region; and
a gate region disposed above the charge storage region;
wherein a cross-section of the first source/drain region, the second source/drain region, the active region, the charge storage region and the gate region have at least a semi-cylindrical shape in the cross-section width direction.

16. The integrated circuit of claim 15, further comprising a gate-isolation region between the active region and the gate region.

17. The integrated circuit of claim 15, wherein the charge storage region comprises a floating gate storage region.

18. The integrated circuit of claim 15, wherein the charge storage region comprises a charge trapping storage region.

19. The integrated circuit of claim 18, wherein the charge trapping storage region comprises at least two dielectric layers that are formed above one another.

20. The integrated circuit of claim 15, wherein the cross-section of the first source/drain region, the second source/drain region, the active region and the gate region having a rounded shape in a range of 190° to 350°.

21. The integrated circuit of claim 15, wherein the bulk semiconductor carrier comprises silicon.

22. An integrated circuit comprising a nanowire transistor field, the nanowire transistor field comprising:
a bulk semiconductor carrier;
a plurality of nanowire transistors, each of the nanowire transistors comprising a nanowire structure formed on the bulk semiconductor carrier, each nanowire structure comprising:
a first source/drain region;
a second source/drain region;
an active region between the first source/drain region and the second source/drain region;
a charge storage region disposed above the active region; and
a gate region disposed above the charge storage region;
wherein a cross-section of the first source/drain region, the second source/drain region, the active region, the charge storage region and the gate region have at least a semi-cylindrical shape in the cross-section width direction;
a plurality of bit lines, each bit line coupled to a plurality of the plurality of nanowire transistors; and
a plurality of word lines, each word line coupled to a plurality of the plurality of nanowire transistors.

23. The integrated circuit of claim 22, wherein the nanowire transistors are coupled in a NAND structure.

24. The integrated circuit of claim 22, wherein at least some of the nanowire transistors further comprises a gate-isolation region between the active region and the gate region.

25. The integrated circuit of claim 22, wherein the charge storage region comprises a floating gate storage region.

26. The integrated circuit of claim 22, wherein the charge storage region comprises a charge trapping storage region.

27. The integrated circuit of claim 26, wherein
the charge trapping storage region comprises a tunnel dielectric, a trapping dielectric, and a blocking dielectric between the gate region and the bulk semiconductor carrier.

28. The integrated circuit of claim 27, wherein the tunnel dielectric comprises a plurality of layers.

29. The integrated circuit of claim 28, wherein the tunnel dielectric comprises a first oxide layer, a nitride layer disposed above the first oxide layer, and a second oxide layer disposed above the nitride layer.

30. The integrated circuit of claim 29, wherein the first oxide layer has a thickness in the range of approximately 1 nm to approximately 2 nm;
the nitride layer has a thickness in the range of approximately 1 m to approximately 3 nm; and
the second oxide layer has a thickness in the range of approximately 1 nm to approximately 2 nm.

31. The integrated circuit of claim 27, wherein the blocking dielectric comprises silicon oxide or a dielectric material having a dielectric constant that is greater than the dielectric constant of silicon oxide.

32. The integrated circuit of claim 27, wherein the blocking dielectric comprises a dielectric material having a dielectric constant that is greater than the dielectric constant of silicon oxide and an energy band gap above 5 eV.

33. The integrated circuit of claim 32, wherein the blocking dielectric comprises aluminum oxide or hafnium silicate.

34. A method of manufacturing a nanowire transistor, the method comprising:
oxidizing at least a portion of a semiconductor carrier, the semiconductor carrier comprising a first carrier portion and a second carrier portion above the first carrier portion;
removing a portion of the oxidized portion, thereby forming an oxide spacer between a portion of the second carrier portion and the first carrier portion;
forming a gate region above at least a portion of the second carrier portion; and
forming a first source/drain region and a second source/drain region in the semiconductor carrier.

35. A non-volatile nanowire memory cell structure, comprising:
a bulk semiconductor carrier;
a nanowire structure formed on the bulk semiconductor carrier, the nanowire structure comprising:
a first source/drain region;
a second source/drain region;
an active region between the first source/drain region and the second source/drain region; and
a gate region disposed above the active region;
wherein a cross-section of the first source/drain region, the second source/drain region, the active region and the gate region have at least a semi-cylindrical shape in the cross-section width direction.

36. A method of manufacturing a nanowire transistor, the method comprising:
oxidizing a portion of a semiconductor carrier, the semiconductor carrier comprising a first carrier portion and a second carrier portion above the first carrier portion;
removing a portion of the oxidized portion, thereby forming an oxide spacer between a portion of the second carrier portion and the first carrier portion;
forming a charge storage region above at least a portion of the second carrier portion;
forming a gate region above at least a portion of the charge storage region; and
forming a first source/drain region and a second source/drain region adjacent the gate region.

37. A nanowire transistor structure, comprising:
a bulk semiconductor carrier;
a nanowire structure formed on the bulk semiconductor carrier, the nanowire structure comprising:
a first source/drain region;
a second source/drain region;
an active region between the first source/drain region and the second source/drain region;
a charge storage region disposed above the active region; and
a gate region disposed above the charge storage region;
wherein a cross-section of the first source/drain region, the second source/drain region, the active region, the charge storage region and the gate region have at least a semi-cylindrical shape in the cross-section width direction.
